(19) United States
(12) Patent Application Publication
(10) Pub. No.: US 2004/0209442 A1
(43) Pub. Date: Oct. 21, 2004

(54) Device manufacturing method and device, electro-optic device, and electronic equipment

(75) Inventors: Atsushi Takakuwa, Shiajiri-shi (JP); Sumio Utsunomiya, Suwa-shi (JP); Tomoyuki Kamakura, Matsumoto-shi (JP); Masashi Kasuga, Suwa-shi (JP); Satoshi Inoue, Chino (JP); Takayuki Saeki, Seto-cho (JP); Mutsumi Kimura, Kyotauabe-shi (JP); Takashi Hashimoto, Chino-shi (JP); Fukumi Tsuchihashi, Chino (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 10/754,538

(22) Filed: Jan. 12, 2004

(30) Foreign Application Priority Data
Jan. 23, 2003 (JP) 2003-015098

(51) Int. Cl. H01L 21/30

(52) U.S. Cl. 438/458

(57) ABSTRACT

The present application provides a manufacturing method for a device which enables manufacture of a device effectively at low cost by dispersingly arranging elements such as TFTs on a final substrate which becomes an active matrix substrate for electro-optic devices, a device obtained by the method, an electro-optic device, and electronic equipment. The method is to prepare a part or all of many elements formed on a first substrate 10 and then these elements are transferred to a second substrate 14. for manufacturing a device. The method has; a first process for forming a separation layer on a first substrate 10; a second process for forming many elements on the separation layer; a third process for adhering the elements to be transferred on the first substrate 10, onto the second substrate 14 via an adhesive layer; a fourth process for exerting a force acting in a direction to separate the first substrate 10 and the second substrate 14, onto the separation layer between the first substrate 10 and the second substrate 14 from one edge of those substrates, and for producing exfoliation in the layer and/or on the interface of the separation layer; and a fifth process for separating the first substrate 10 from which the transfer of elements has been completed, from the second substrate 14.

### BACKGROUND OF THE INVENTION

Priority is claimed on Japanese Patent Application No. 2003-015098, filed Jan. 23, 2003, the content of which is incorporated herein by reference.

1. Field of the Invention

The present invention relates to a manufacturing method for a device, which manufactures a device by transferring elements, a device manufactured by the method, an electro-optic device, and electronic equipment.

2. Description of the Related Art

Recently, for electro-optic devices such as liquid crystal electro-optic devices, active matrix type devices which use thin film elements such as thin film transistors (hereunder, TFT), thin film diodes (hereunder, TFD) or the like, have become the mainstream. However, regarding the conventional electro-optic devices furnished with amorphous silicon TFT or poly-crystalline silicon TFT, manufacturing cost per unit area is expensive. Hence, in the case where large electro-optic devices are to be manufactured, a problem is that the cost becomes very expensive. One cause for this is the effective area ratio utilized for the transistors on the substrate of the liquid crystal electro-optic device is low, and wastage of the thin film element constituent material which forms the film is considerable. That is to say, in the case where amorphous silicon TFT or poly-crystalline silicon TFT are to be formed on the substrate by the conventional techniques, after film-forming the amorphous silicon on one side by CVD or the like, the unnecessary area is removed by etching. However, the TFT circuit area inside the pixel area is only from a few % to several 10% and the thin film element constituent material which is film-formed on the rest of pixel electrode part is discarded by etching. In cases where it is possible to effectively manufacture only the TFT circuit section on the substrate, it is possible to greatly reduce the cost, especially of large electro-optic devices. Therefore various techniques have been studied.

Conventionally, as a technique for arranging an LSI circuit which is manufactured on a silicon wafer, onto another substrate, a so called microstructure method developed by Alien Technology Co. is well known (for example, refer to Non Patent Document 1).

The microstructure technique is characterized in that it involves separating LSI circuits manufactured on a silicon wafer into microchips (=microstructures), and then pouring solvent dispersed with the microstructures onto a substrate previously patterned with holes for filling, so that the microstructures are arranged at predetermined positions on the substrate. According to this microstructure technique, microstructures which are formed in a large number on a silicon wafer can be dispersingly arranged on a substrate. Moreover, since this gives a discrete type arrangement where unit elements are separated on the substrate, the ability to follow the curvature and bending of the substrate is excellent, so that it is applicable to flexible substrates.

However, in the microstructure technique, there is the problem in that reliable arrangement of the microstructures on the substrate and accurate positioning are difficult. Moreover, since the directions in which the microstructures are arranged are random, special circuits to cope with this must be provided for the microstructures, with the problem of incurring a cost increase. In the present state, this problem is avoided by designing four-fold rotationally symmetry into the circuits on microstructures.

Further, in the manufacture of color filters of liquid crystal displays, a method called an LITI process is well known, in which; a donor sheet formed by the sequential lamination of respective layers of; substrate/adhesion layer/photo-absorption layer/protective layer/colored film layer/thermal melting adhesion layer, is superposed on a transfer substrate; the photo-absorption layer is then photo-irradiated for a partial area of the donor sheet; heat generated here melts and adheres the thermal melting adhesion layer; and as a result only the photo-irradiated area is transferred onto the substrate (for example, refer to Patent Document 1).

However, this conventional technique is used for manufacturing color filters or the like for liquid crystal display elements, and other application possibilities have not been specified.

Furthermore, as a method for transferring a thin film element such as a TFT or the like formed on a substrate, to a destination body, the present applicant has developed and applied to patent, a transferring method for a thin film element, which is characterized in having; a process for forming a separation layer on a substrate of high reliability and which can transmit laser light; a process for forming a to-be-transferred layer containing a thin film element on the separation layer; a process for adhering the to-be-transferred layer containing the thin film element to the destination body via an adhesion layer; a process for photo-irradiating the separation layer and generating exfoliation in the layer and/or on interface of the separation layer; and a process for separating the substrate from the separation layer (refer to Patent Document 2).

Likewise, the present applicant has developed and applied to patent a method for transferring a thin film element, which is characterized in having: a first process for forming a first separation layer on a substrate; a second process for forming a to-be-transferred layer containing a thin film device on the first separation layer; a third process for forming a second separation layer on the to-be-transferred layer; a fourth process for adhering a primary destination body on the second separation layer, a fifth process for removing the substrate from the to-be-transferred layer with the first separation layer made a border, a sixth process for adhering a secondary destination body on the undersurface of the to-be-transferred layer, and a seventh process for removing the primary destination body from the to-be-transferred layer with the second separation layer made a border; and the to-be-transferred layer containing the thin film device is transferred to the secondary destination body (refer to Patent Document 3).

According to these transfer techniques, it is possible to transfer a finely structured and high-performance functional device onto a desired substrate.

[Non Patent Document 1]

Information DISPLAY, Vol.15, No. 11 (November 1999)

[Patent Document 1]

U.S. Pat. No. 6,057,067 Specification

[Patent Document 2]

Japanese Unexamined Patent Application, First Publication No. Hei 10-125931

[Patent Document 3]

Japanese Unexamined Patent Application, First Publication No. Hei 11-26733

However, the conventional transfer techniques have the following problems.

That is to say, since the conventional transfer techniques are to transfer all of the thin film elements such as TFTs, which are formed on the substrate onto the final substrate, then as with an active matrix substrate for electro-optic devices, a large number of TFTs are required. However, in order to manufacture a substrate for which the defined area of the TFTs is small with respect to the whole substrate area, it is necessary to specially manufacture a substrate where a large number of TFTs are formed at the same intervals as for the final substrate, and transfer these to the final substrate, or it is necessary to repeat the transfer many times, which does not always give a reduction in cost.

Further, since the conventional transfer techniques are to transfer all the thin film elements such as TFTs which are formed on the substrate onto the final substrate, then the larger the area of the substrate, the higher the characteristic required for the irradiating laser light, that is, the higher the power and uniformity, so that it becomes difficult to obtain a laser light source which satisfies the required performance, and large sized highly accurate irradiation equipment becomes necessary for the laser light irradiation. In addition, when irradiating a high power laser light, the thin film elements may be heated above their heat resistant critical temperature, so that the function of the thin film element itself may be lost. Hence, there is the problem that the transfer process itself becomes difficult.

Furthermore, similarly to the conventional transfer techniques, in the case where the thin film elements formed on the substrate are transferred in device units, for example, an insulating film is continuously formed over the whole surface of the thin film element. Therefore cracking may occur when the final substrate is bent after the transfer, and the ability to follow the bending of the substrate is not good. As a result, in the conventional transfer techniques, the degree of freedom for selecting the final substrate is limited.

### SUMMARY OF THE INVENTION

The present invention takes into consideration the above situation with the object of providing, a manufacturing method for a device which enables the manufacture a device effectively at low cost, by dispersingly arranging elements such as TFTs on a final substrate which becomes an active matrix substrate for an electro-optic device, and a device, an electro-optic device, and electronic equipment obtained by the method.

In order to achieve the above object, a manufacturing method for a device of the present invention, in which a part of, or all of many elements formed on a first substrate, are transferred to a second substrate, and a part of, or all of the transferred elements are used to manufacture the device, is characterized in having; a first process for forming an separation layer on said first substrate; a second process for forming many elements on said separation layer; a third process for adhering the elements to be transferred on said first substrate, to said second substrate via an adhesive layer; a fourth process for exerting a force acting in a direction to separate said first substrate and said second substrate on the separation layer between said first substrate and said second substrate from one edge of those substrates, to execute exfoliation in the layer and/or on an interface of the separation layer; and a fifth process for separating said first substrate from which the transfer of elements has been completed, from said second substrate.

According to the manufacturing method for a device of the present invention, for example, by assuming the second substrate is to be the final substrate for device forming, or by assuming a substrate to which elements are additionally transferred from the second substrate is to be the final substrate, it becomes possible to concentratedly manufacture on the first substrate, the many elements which are to be dispersingly arranged with intervals on the final substrate. Hence, compared to the case where elements are directly formed on the final substrate, it is possible to greatly increase the area efficiency of the substrate when manufacturing elements. Consequently, it becomes possible to manufacture effectively and at low cost, a final substrate where many elements are dispersingly arranged. As a result, the device itself can be effectively manufactured at low cost.

Moreover, it is possible to easily execute prior to transfer, selection and removal of the many elements which are concentratedly manufactured on the first substrate. As a result, product yield rate can be increased.

Furthermore, since a force is exerted on the separation layer between the first substrate and the second substrate acting in a direction to separate these substrates, from one edge of these substrates, exfoliation of the separation layer at the layer and/or on the interface, is easily produced. Hence, the separation layer and the elements are separated, and the elements are reliably transferred onto the second substrate.

Moreover, it is possible to laminate and unite the same or different elements. Therefore, by uniting the elements manufactured in different process conditions, an element having a laminated structure which is conventionally difficult to manufacture can be provided, and an element having a three-dimensional structure can be easily manufactured.

In the manufacturing method for a device, preferably transfer of the elements from the first substrate to the second substrate involves collectively transferring all the elements formed on the first substrate.

In this manner, in order to collectively transfer all the elements, it is necessary to separate the whole separation layer. However, as described above, since a force is exerted on the separation layer between the first substrate and the second substrate acting in a direction to separate these substrates, from one edge of these substrates, exfoliation of the separation layer at the layer and/or on the interface, is easily produced.

In the manufacturing method for a device, it is preferable to have; a sixth process for forming after separating said first substrate from said second substrate, a thin film element providing substrate by providing a heat fusion sheet containing heat sealing adhesive on said elements which have been transferred to said second substrate; a seventh process for superposing a final substrate so that it contacts with said heat fusion sheet of said thin film element providing substrate, selectively irradiating light only on the area of said elements to be transferred, and adhering only said elements to be transferred onto the final substrate for device forming; and an eighth process for removing said thin film element providing substrate having untransferred elements, from the final substrate to which said elements have been transferred.

In this manner, by sequentially performing the respective processes, and by superposing the thin film element providing substrate and the final substrate, and irradiating light only on the part to be transferred, some of the many elements on the thin film element providing substrate side can be accurately transferred onto the final substrate.

Further, since the easily handled thin film element providing substrate which transfers of all of the elements formed on the first substrate onto the second substrate is made, and then the thin film element providing substrate is superimposed onto the final substrate, to transfer only the elements to be transferred to the final substrate, the elements can be transferred onto the final substrate while keeping the vertical relationship of the laminated structure of the elements formed on the first substrate. Therefore, extra improvement such as changing the position of external joining terminals in order to handle cases where the vertical relationship is reversed, is not necessary, so that it is possible to manufacture elements using an existing element manufacturing process.

In the manufacturing method for a device, it is preferable to have a pre-exfoliation process between said third process and said fourth process, for selectively irradiating light onto said separation layer between said elements to be transferred and said first substrate, to execute exfoliation in the layer and/or on the interface of said separation layer.

In this manner, since in the pre-exfoliation process, exfoliation is produced in the layer and/or on the interface of the separation layer, then by additionally exfoliating the separation layer in the following fourth process, separation of the first substrate from the second substrate becomes reliable and easy.

In the manufacturing method for a device, preferably said fourth process is performed by inserting a sharp edge body into one edge between said first substrate and said second substrate.

In this manner, it is easy to execute exfoliation in the layer and/or on the interface of the separation layer, and separation of the first substrate from the second substrate becomes reliable and easy.

In the manufacturing method for a device, preferably said fourth process is performed by injecting a high pressure gas into one edge between said first substrate and said second substrate.

In this manner, it is easy to execute exfoliation in the layer and/or on the interface of the separation layer, and separation of the first substrate from the second substrate becomes reliable and easy.

In the manufacturing method for a device, preferably said fourth process is performed by injecting a liquid into one edge between said first substrate and said second substrate.

In this manner, it is easy to execute exfoliation in the layer and/or on the interface of the separation layer, and separation of the first substrate from the second substrate becomes reliable and easy.

In the manufacturing method for a device, preferably said fourth process is performed by moving one of the edges of said first substrate and said second substrate in a direction to separate from the other of the edges of said first substrate and said second substrate.

In this manner, it is easy to execute exfoliation in the layer and/or on the interface of the separation layer, and separation of the first substrate from the second substrate becomes reliable and easy.

In the manufacturing method for a device, it is preferable to provide a thermal expansion material in one edge of said separation layer when forming the separation layer in said first process, and to perform said fourth process by thermal expansion of said thermal expansion material by heat treatment.

In this manner, it is easy to execute exfoliation in the layer and/or on the interface of the separation layer, and separation of the first substrate from the second substrate becomes reliable and easy.

In the manufacturing method for a device, preferably said fourth process is performed by laser ablating the separation layer by irradiating laser light onto one edge between said first substrate and said second substrate.

In this manner, it is easy to execute exfoliation in the layer and/or on the interface of the separation layer, and separation of the first substrate from the second substrate becomes reliable and easy.

The device of the present invention is characterized in being obtained by the aforementioned manufacturing methods.

According to this device, it is manufactured effectively at low cost, and product yield rate is also increased.

The electro-optic device of the present invention, is characterized in being equipped with the aforementioned device.

According to this electro-optic device, the device is manufactured effectively at low cost and product yield rate is also increased, so that the electro-optic device itself is also manufactured at low cost.

The electronic equipment of the present invention, is characterized in being equipped with the aforementioned device.

According to this electronic equipment, the device is manufactured effectively at low cost and product yield rate is also increased, so that the electronic equipment itself is also manufactured at low cost.

### BRIEF DESCRIPTION OF THE DRAWINGS

FIG. 1 is an explanatory diagram of a first embodiment of a device of the present invention, and a cross-section showing a first process for forming a separation layer on a first substrate.

FIGS. 2A, 2B, and 2C are explanatory diagrams of a second process for forming many elements on a separation layer, 2A being a cross-section showing a condition where many elements are formed on the separation layer, 2B being an enlarged cross-section of a main part for describing another example of formation, and 2C being an enlarged cross-section for showing a device.

FIG. 3 is a cross-section showing a condition where a multilayer film is formed on a second substrate.

FIG. 4 is a cross-section showing a third process for adhering the first substrate and the second substrate, and a fourth process for producing exfoliation of a separation layer by partial irradiation of light from the first substrate side.

FIG. 5 is an explanatory diagram of an example of a method for exerting a force acting in a direction to separate the first substrate and the second substrate.

FIG. 6 is a schematic diagram showing an example of an exfoliation device furnished with a sharp edge body.

FIG. 7 is an explanatory diagram of another example of a method for exerting a force acting in a direction to separate the first substrate and the second substrate.

FIG. 8 is a cross-section showing a sixth process for manufacturing a thin film element providing substrate.

FIG. 9 is a cross-section showing a seventh process, for superposing a final substrate on the thin film element providing substrate, and for selectively irradiating light only to the area of the elements to be transferred, so that only the elements to be transferred are transferred to the final substrate.

FIG. 10 is a cross-section showing an eighth process for removing the final substrate from the second substrate after finishing the transfer.

FIG. 11 is an explanatory diagram of a second embodiment of the device manufacturing method of the present invention, and a cross-section showing a (d) process for irradiating light onto the separation layer of the first substrate in order to transfer elements to the second substrate side.

FIG. 12 is a cross-section showing a condition where the first substrate is removed from the elements transferred to the second substrate side.

FIG. 13 is a cross-section showing an (f) process for adhering a third substrate on which is previously formed a multilayer film, onto the elements transferred to the second substrate side.

FIG. 14 is a cross-section showing an (h) process for forming a thin film element providing substrate.

FIGS. 15A, 15B, and 15C are diagrams showing electronic equipment related to the present invention, 15A showing an example of a mobile phone, 15B being showing an example of a portable information processor, and 15C showing an example of a watch type electronic equipment.

### DETAILED DESCRIPTION OF THE INVENTION

Hereunder is a description of embodiments of the present invention, with reference to the drawings.

### First Embodiment

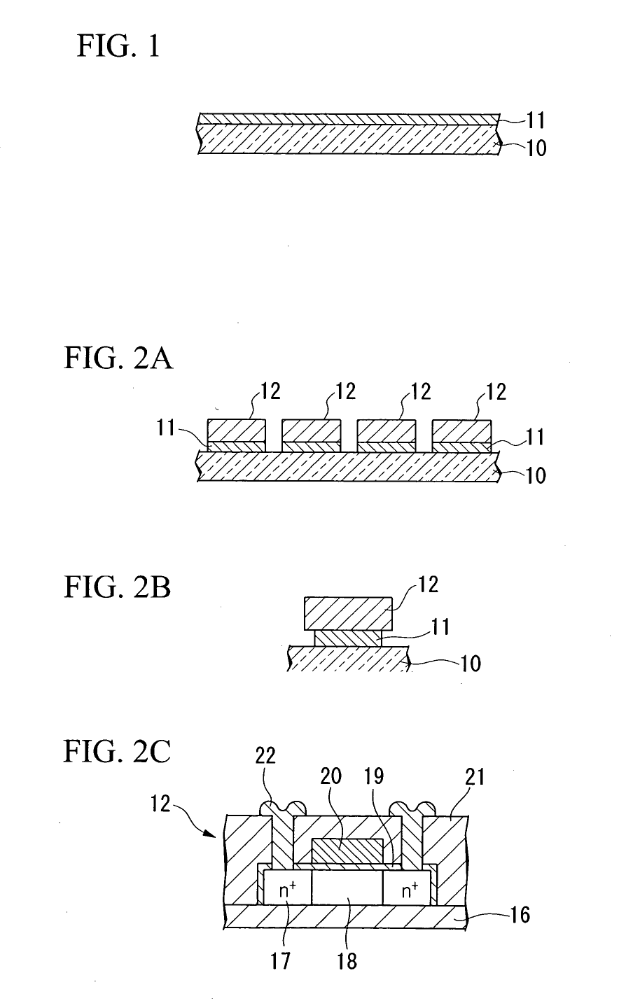

FIG. 1 to FIG. 10 are explanatory drawings of a first embodiment of a manufacturing method for a device of the present invention. The manufacturing method is performed through the following first process to eighth process.

[First Process]

In the first process, as shown in FIG. 1 a separation layer (photoabsorption layer) 11 is formed on a first substrate 10.

The first substrate 10 preferably has transmittance that allows transmission of light.

In this case, the transmissivity of light is preferably more than 10%, and more preferably more than 50%. If the transmissivity is too low, the loss of light becomes large, and a larger quantity of light is required in order to exfoliate the separation layer 11.

Moreover, preferably the first substrate 10 is constructed from highly reliable material, specifically, it is preferably constructed from materials with superior heat resistance. The reason is that for example, when forming an element 12 or intermediate layer 16 described later, the process temperature may become high depending on the type or formation method (for example, around 350 to 1000° C.). However, even in such a case, if the substrate 10 is superior in heat resistance, then when forming the element 12 on the first substrate 10, the range of settings for the film forming conditions such as the temperature conditions and the like, can be wider.

Therefore, if the maximum temperature when forming the element 12 is Tmax, the first substrate 10 is preferably manufactured from a material with a distortion point greater than Tmax. Specifically, the constituent material for the first substrate 10, preferably has a distortion point greater than 350° C., and more preferably has a distortion point greater than 500° C. As such materials, heat resistant glass such as quartz glass, Coming 7059, and OA-2 made by Nippon Electric Glass Co. are given as examples.

The thickness of the first substrate 10 is not specifically limited. However, it is preferably around 0.1 to 5.0 mm, and more preferably around 0.5 to 1.5 mm. If the thickness of the first substrate 10 is too thin, the strength drops, while if too thick, then in the case where the transmissivity of the first substrate 10 is low, attenuation of light can easily occur. In the case where the transmissivity of the first substrate 10 is high, the thickness may be greater than the aforementioned upper limit. In order to evenly irradiate the light, the thickness of the first substrate 10 is preferably uniform.

The separation layer 11 is formed by materials which easily execute exfoliation by the action of mechanical force. That is to say, it is formed by such materials that; when a force acting on the separation layer 11 in a direction to separate the first substrate 10 and a later described second substrate, is applied from one edge those substrates, it easily produces exfoliation in the layer and/or on interface of the separation layer 11 (hereunder, “internal exfoliation” and “interfacial exfoliation”).

Further, such a separation layer 11 preferably has a characteristic of absorbing irradiated light and producing exfoliation in the layer and/or on the interface, that is to say, internal exfoliation and/or interfacial exfoliation. Specifically, it is desired that the interatomic or intermolecular binding strength of the constituent material of the separation layer 11 is eliminated or reduced by light irradiation, that is, ablation is produced ending in internal exfoliation and/or interfacial exfoliation.

Furthermore, in some cases gas will be released from the separation layer 11 by the light irradiation, to manifest the separation effect. That is to say, there is the case where an element contained in the separation layer 11 becomes a gas and is released, and the case where the separation layer absorbs the light and instantly becomes a gas and the vapor thereof is released to contribute to the separation.

Examples of the constituent materials for the separation layer 11, are those described in A-F hereunder.

A. Amorphous silicon (a-Si) This amorphous silicon may contain hydrogen (H). In this case, it is preferable that the H content be approximately 2 atomic percent or more, and more preferably 2 to 20 atomic percent. When a predetermined amount of hydrogen (H) is contained in this manner, hydrogen is released by light irradiation and an internal pressure is generated in the separation layer 11, becoming a force to separate the upper and lower thin films. The hydrogen (H) content in the amorphous silicon can be controlled by appropriately setting the film forming conditions, for example, the gas composition, gas pressure, gas atmosphere, gas flow rates, temperature, substrate temperature and input power in the CVD.

B. Oxide ceramics, dielectrics (ferroelectrics) and semiconductors, such as silicon oxides and silicates, titanium oxides and titanates, zirconium oxide and zirconates, and lanthanum oxide and lanthanates. Examples of silicon oxides include SiO, SiO₂, and Si₃O₂, and examples of silicates include K₂SiO₃, Li₂SiO₃, CaSiO₃, ZrSiO₄, and Na₂SiO₃.

Examples of titanium oxides include TiO, Ti₂O₃, and TiO₂, and examples of titanates include BaTiO₄, BaTiO₃, Ba₂Ti₉O₂₀, BaTi₅Ol₁, CaTiO₃, SrTiO₃, PbTiO_{ZrTiO}₂, SnTiO₄, Al₂TiO₅ and FeTiO₃.

Examples of zirconium oxides include ZrO₂, and examples of zirconates include BaZrO₂, ZrSiO₄, PbZrO₃, MgZrO₃ and K₂ZrO₃.

C. Ceramics and dielectrics (ferroelectrics), such as PZT, PLZT, PLLZT, PBZT.

D. Nitride ceramics, such as silicon nitride, aluminum nitride, titanium nitride.

E. Organic polymers:

Usable organic polymers have bonds (which are cut by irradiation of the light), such as —CH—, —CO— (ketone), —CONH— (amide), —NH— (imide), —COO— (ester), —N═N— (azo), —CH═N— (cis). In particular, any organic polymers having large numbers of such bonds can be used. The organic polymers may have aromatic hydrocarbons (one or more benzene rings or fused rings) in the chemical formulae.

Examples of the organic polymers include polyolefins, such as polyethylene, and polypropylene; polyimides; polyamides; polyesters; polymethyl methacrylate (PMMA); polyphenylene sulfide (PPS); polyether sulfone (PES); and epoxy resins.

F. Metals

Examples of metals include Al, Li, Ti, Mn, In, Sn, Y, La, Ce, Nd, Pr, Gd, Sm, and alloys containing at least one of these metals.

The thickness of the separation layer 11 depends on various conditions, such as the purpose for exfoliation, the composition of the separation layer 11, the layer configuration, and the method for forming the layer. However, normally a thickness of around 1 nm to 20 μm is preferable, more preferably around 10 μm to 2 μm, and even more preferably around 40 nm to 1 μm. If the film thickness of the separation layer 11 is too small, uniformity in deposition may be lost, and nonuniformity may occur in the separation. If the film thickness is too thick, then in order to maintain good peelability of the separation layer 11, it is necessary to increase the power of light (quantity of light), and when removing the separation layer 11 later, the operation takes time. It is preferable that the thickness of the separation layer 2 be as uniform as possible.

The method for forming the separation layer 11 is not limited, and is determined depending on several conditions, such as the film composition and thickness. Examples of the methods include vapor phase deposition processes, such as CVD (including MOCVD, low pressure CVD, ECR-CVD), evaporation, molecular beam (MB) evaporation, sputtering, ion-plating, and PVD; plating processes, such as electroplating, dip-plating (dipping), and electroless-plating; coating process, such as a Langmuir-Blodgett process, spin-coating process, spray-coating process, and roll-coating process; printing processes; transfer processes; ink-jet processes; and powder-jet processes. A combination of these processes may also be used.

For example, when the separation layer 11 is composed of amorphous silicon (a-Si), it is preferable that the layer be formed by a CVD process, specifically a low pressure CVD or plasma CVD process.

When the separation layer 11 is formed from a ceramic by a sol-gel process, or formed from an organic polymer, it is preferable that the layer be formed by a coating process, and particularly a spin-coating process. Further, although not shown in FIG. 1, depending on the properties of the first substrate 10 and the separation layer 11, an intermediate layer may be arranged between the first substrate 10 and the separation layer 11 with an object of increasing the adhesion of both.

[Second Process]

Next, many elements 12 are formed on the separation layer 11, after which an etching process is performed so that the respective elements 12 and the separation layer 11 immediately beneath remain as islands. The result is such that, as shown in FIG. 2(a), the many transferred layers (elements 12) are arranged at predetermined intervals via the separation layer 11 on the first substrate 10. In this manner, by forming the elements 12 being the transferred layers, and the separation layer 11 as islands, it becomes easy to transfer only the desired elements 12 in an exfoliation process described later.

The separation layer 11 divided for each of the respective elements 12, as shown in FIG. 2(a), may be the same size as the separation layer adhesion face of the element 12. However, it may be such that, as shown in FIG. 2(b), the separation layer 11 is further over-etched so that the adhesion area of the separation layer 11 to the element 12 becomes smaller than the whole area of the separation layer adhesion face of element 12. In this manner, by over-etching the separation layer 11, then when the mechanical force is exerted on the separation layer 11, exfoliation is easily produced at the separation layer 11. Furthermore as described later, when irradiating light as a pre-exfoliation process, exfoliation is easily produced. Moreover, by reducing the separation layer 11, the amount of light energy required for exfoliation can be reduced.

FIG. 2(c) is a cross-section showing an example of the element 12 used in the present embodiment. The element 12 is constructed to contain for example a TFT (thin film transistor) formed on an SiO₂ film (intermediate layer) 16. The TFT is equipped with a source and drain area 17 formed by introducing an n-type impurity to the poly-crystalline silicon layer, a channel area 18, a gate insulating film 19, a gate electrode 20, an interlayer insulating film 21, and an electrode 22 composed of for example aluminum. The element 12 it is not limited to a TFT, and various elements such as a silicon base transistor, an SOI (silicon on insulator) and the like may be applied.

In the present invention, as the intermediate layer provided in contact with the separation layer 11, an SiO₂ film is used, however, other insulating films such as Si₃N₄ may be used. The thickness of the SiO₂ film (intermediate layer) is adequately determined corresponding to the purpose for the formation, and the degree of function to be demonstrated, however normally around 10 nm to 5 μm is preferable, and 40 nm to 1 μm is more preferable. The intermediate layer is formed for various purposes, and functions as at least one of, a protective layer for physically or chemically protecting the transferred layer (element 12), an insulating layer, a conductive layer, a shading layer to laser light, a barrier layer for preventing migration, and a reflection layer.

In some cases, the transferred layer (element 12) may be directly formed on the separation layer 11, by omitting the formation of the interlayer, such as the SiO₂ film.

The transferred layer (element 12) includes a thin film element such as a TFT, as shown in FIG. 2(c). As a thin film element, besides the TFT, there are for example: thin film diodes, photoelectric transducers comprising a PIN junction of silicon (photosensor, solar battery), silicon resistive elements, other thin film semiconductor devices, electrodes (for example; transparent electrodes such as ITO and mesa film), switching devices, memories, actuators such as piezoelectric devices, micromirrors (piezoelectric thin film ceramics), magnetic recording thin film heads, coils, inductors, thin film high permeability materials and micro-magnetic devices composed of combinations thereof, filters, reflection films, dichroic mirrors, and the like.

Such thin a film element (thin film device) is normally formed by a comparatively high process temperature due to the forming method therefor. Therefore, in this case, as described above, the substrate 10 must be a highly reliable material which is resistant to this process temperature.

[Third Process]

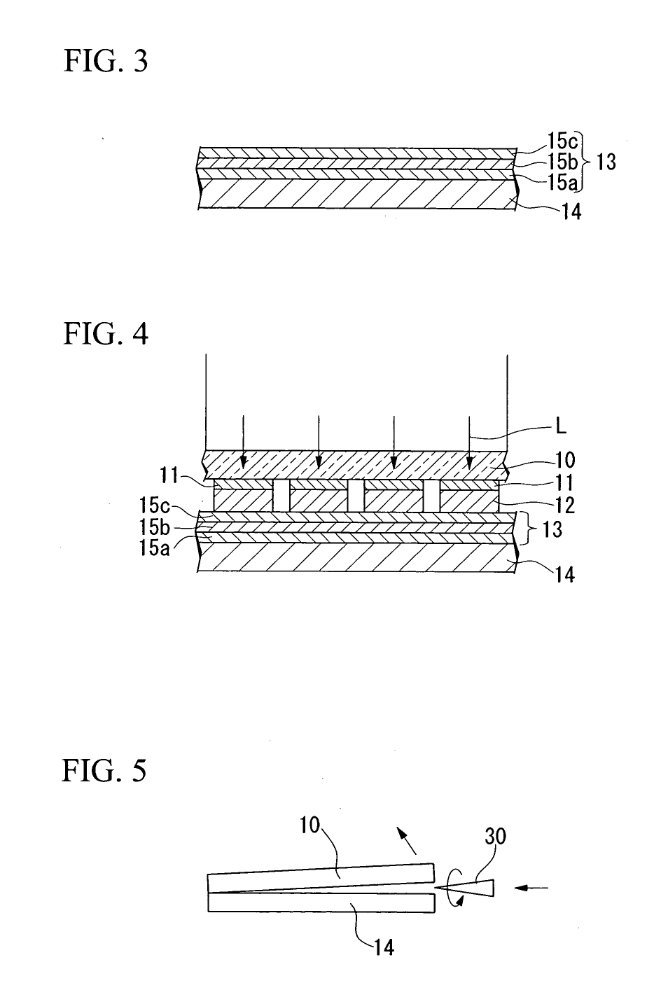

On the other hand, as shown in FIG. 3, on a second substrate 14, is formed a multilayer film 13 made by sequentially laminating a protective layer 15a, a photoabsorption layer 15b, and an adhesive layer 15c.

Next, as shown in FIG. 4, the first substrate 10 is superposed onto the adhesive layer 15c of the second substrate 14, and all of the many thin film elements 12 which are formed on the first substrate 10 are adhered onto the second substrate via the adhesive layer 15c.

In the case of transferring not all but only a part of the many thin film elements 12 formed on the first substrate 10, the adhesive layer 15c which is formed beforehand on the second substrate 14, is formed corresponding to only the elements to be transferred. In the formation of such adhesive layer 15c, for example, a droplet application method (ink jet method) is suitably used, since this can accurately apply adhesive to the arbitrary points.

The second substrate 14, is not specifically limited, and may be a substrate (plate material), specifically a transparent substrate. Such a substrate may be flat or curved. Further, the second substrate 14 may be inferior to the first substrate 10 in characteristics such as heat resistance, corrosion resistance, and the like. The reason is that; since in the present invention, the elements 12 are formed on the first substrate 10, and then the elements 12 are transferred to the second substrate 14, the characteristics required for the second substrate 14, specifically heat resistance, are not dependent on the temperature conditions when forming the elements 12.

Therefore, if the maximum temperature when forming the element 12 is T max, a constituent for the second substrate 14 with a glass transition point (Tg) or a softening point below T max can be used. For example, the second substrate 14 can be formed from a material with a glass transition point or softening point preferably below 800° C., more preferably below 500° C., and even more preferably below 320° C.

As the mechanical characteristics of the second substrate 14, it is preferable to have a degree of rigidity (strength), however, it may have flexibility or elasticity.

As such a constituent for the second substrate 14, there are various synthetic resins or various glasses. In particular, various synthetic resins or normal (low melting point) low cost glass are preferable.

Examples of synthetic resins include both thermoplastic resins and thermosetting resins such as; polyolefins, e.g. polyethylene, polypropylene, ethylene-propylene copolymers, and ethylene-vinyl acetate copolymers (EVAs); cyclic polyolefins; modified polyolefins; polyesters such as polyvinyl chloride, polyvinylidene chloride, polystyrene, polyamides, poly-imides, polyamide-imides, polycarbonates, poly-(4-methylpentene-1), ionomers, acrylic resins, polymethyl methacrylate, acrylic-styrene copolymer (AS resin), butadiene-styrene copolymers, polio copolymers (EVOHs), polyethylene terephthalate (PET), polybutylene terephthalate (PBT), polycyclohexane terephthalate (PCT) and the like; polyethers, polyether-ketones (PEKs), polyether-ether-ketones (PEEKs), polyethe-imides, polyacetals (POMs); polyphenylene oxides; modified polyphenylene oxides; polyalylates; aromatic polyesters (liquid crystal polymers), polytetrafluoroethylene, polyvinylidene fluoride, and other fluorine resins; various thermoplastic elastomers such as styrene-, polyolefin-, polyvinyl chloride-, polyurethane-, fluorine rubber-, chlorinated polyethylene-type, and the like; epoxy resins, phenol resins, urea resins, melamine resins, unsaturated polyesters, silicone resins, polyurethanes, and the like; and copolymers, blends, polymer alloys essentially consisting of these synthetic resins. One or more of these synthetic resins may be used in combination (for example, as a composite consisting of at least two layers).

Examples of glass include, silicate glass (quartz glass), alkaline silicate glass, soda-lime glass, potash lime glass, lead (alkaline) glass, barium glass, and borosilicate glass. All the types of glass other than silicate glass have lower melting points than that of silicate glass. Moreover, they are comparatively easy to form and process, and inexpensive, and therefore preferable.

Of the layers forming the multilayer film 13, the protective layer 15a is for protecting the second substrate from the heat generated in the photoabsorption layer 15b when irradiating the light to the multilayer film 13. Examples of constituents for such a protective layer 15a include, inorganic films such as SiOx, Si₃N₄ and synthetic resin materials.

Examples of constituents for the photoabsorption layer 15b, are selected from among materials which can convert the irradiated light into heat, for example, silicon, metals, carbon black, and photopolymeric monomers or oligomers.

Suitable example of adhesives for forming the adhesive layer 15c, include various hardening type adhesives such as response hardening adhesives, thermosetting adhesives, photo-curing adhesives such as ultraviolet hardening adhesives, and anaerobic hardening adhesives. Examples of compositions of the adhesive include any of the epoxy-type, acrylate-type , and silicon-type compositions.

[Pre-exfoliation Process]

In this manner, after adhering the element 12 to be transferred on the first substrate 10, via the adhesive layer 15c onto the second substrate 14, the operation shifts to the fourth process which is the exfoliation process. However, prior to this, it is preferable to perform a pre-exfoliation process. Needless to say the operation may directly shift to the fourth process without performing the pre-exfoliation process.

In the pre-exfoliation process, as shown in FIG. 4, light L is irradiated against the adhered body of the first substrate 10 and the second substrate 14, from the first substrate 10 side to the whole surface of the separation layer 11, to produce internal and/or interfacial exfoliation of the separation layer. Due to the exfoliation of the separation layer 1, most of the elements 12 are separated from the separation layer 11, giving a condition where they are adhered only to the second substrate 14.

The theory of the occurrence of internal exfoliation and/or interfacial exfoliation in the separation layer 11 presumes the occurrence of ablation in the constituents of the separation layer 11, the release of gas contained in the separation layer 11, or a phase transition such as melting or transpiration generated immediately after the irradiation.

The word “ablation” means that solid components (the constituents of the separation layer 11), which absorbed the incident light, are photochemically and thermally excited and atoms or molecules on the surface or inside the solid components are released by the chain scission. The ablation is mainly observed as phase transition such as melting or vaporization in the partial or entire constituents of the separation layer 11. Also, fine foaming may be formed by the phase transition, resulting in a decreased adhering force.

The internal and/or interfacial exfoliation of the separation layer 11 depends on the composition of the separation layer 11 and other factors, for example, the type, wavelength, intensity and, range of the incident light.

Any type of incident light which causes internal and/or interfacial exfoliation of the separation layer 11, can be used, for example, X-rays, ultraviolet rays, visible rays, infrared rays (heat rays), laser beams, milli-waves, micro-waves, electron rays, and radiations (.α.-rays, β-beta rays, and γ-rays).

Among them, laser beams are preferable because they can easily cause exfoliation (ablation) of the separation layer 11, and are capable of highly accurate local irradiation. Laser light is coherent light and preferable for causing exfoliation at the desired part by irradiating the high powered pulse light the via the first substrate 10 onto the separation layer. Hence, by using laser light, it becomes possible to easily and reliable exfoliate the elements 12.

Examples of lasers generating the laser beams include various gas lasers and solid lasers (semiconductor lasers), and excimer lasers, Nd-YAG lasers, Ar lasers, CO₂ lasers, CO lasers, and He—Ne lasers may be preferably used.

The laser light preferably has a wavelength of 100 nm to 350 nm. In this manner, by using the short wavelength laser light, light irradiation accuracy becomes higher and the exfoliation in the separation layer 11 can be effectively performed.

Example of laser light that satisfies the above conditions include excimer lasers. The excimer laser is a gas laser, which is capable of outputting laser light with high energy in the short wavelength UV range. Four typical types of laser light can be output (XeF=351 nm, XeCl=308 nm, KrF=248 nm, ArF=193 nm) by combinations of rare gasses (Ar, Kr, and Xe) and halogen gasses (F₂ and HCl) as the laser media. Since the excimer laser outputs high energy in short wavelength area, it can cause ablation of the separation layer 11 in an extremely short time. Hence it can exfoliate the separation layer 11 without deteriorating or damaging to the adjacent element 12.

Alternatively, in the case of imparting exfoliation characteristic to the separation layer 11 by causing phase changes such as gas evolution, vaporization and sublimation, the wavelength of the irradiating laser light is preferably around 350 to 1200 nm.

Laser light of such wavelengths may use a laser light source or irradiating device widely used in general processing fields, such as a YAG or gas laser, so that light irradiation can be performed easily at low cost. By using such laser light of wavelength in the visible light range, the first substrate 10 need only be visible light transmitting, thus widening the degree of freedom for selecting the first substrate 10.

Preferably, the energy density of the incident laser light, and particularly of the excimer lasers, ranges from approximately 10 to 5,000 mJ/cm², and more preferably approximately 100 to 1,000 mJ/cm². The irradiation time preferably ranges from 1 to 1,000 nsec., and more preferably from 10 to 200 nsec. At an energy density or irradiation time which is lower than the lower limit, satisfactory ablation will not occur, whereas at an energy density or irradiation time which is higher than the upper limit, the element 12 is adversely affected by the incident light passing through the separation layer 11.

As a solution to the case where the irradiating light which has passed through separation layer 11 reaches and adversely affects the element 12, for example, there is a method where a metal film 11 such as tantalum(Ta) is formed on the separation layer 11. Accordingly, the laser light which has passed through the separation layer 11 is fully reflected at the interface of the metal film, and thus does not adversely affect the elements 12 thereabove.

It is preferable that the incident light including laser beams be incident on the separation layer with a uniform intensity. The incident light may be incident on the separation layer 11 from the direction perpendicular to the separation layer 11 or from a direction shifted by a given angle from the perpendicular direction.

When the separation layer 11 has an area which is larger than the area per scanning of the incident light, the entire separation layer 11 may be irradiated with several scans of incident light. The same position may be irradiated two or more times. The same position or different positions may be irradiated with different types and/or wavelengths of incident (laser) light beams two or more times.

[Fourth Process]

After performing the pre-exfoliation process in this manner, or directly after the third process and not performing the pre-exfoliation process, the fourth process which is the main process of the exfoliation is performed. That is to say, in the fourth process, a force acting in the direction to separate the first substrate 10 and the second substrate 14 is exerted on the separation layer 11 between the first substrate 10 and the second substrate 14 from one edge of these substrates, to execute exfoliation in the layer and/or on an interface of the separation layer 11. In the case where the pre-exfoliation process has been performed, exfoliation has been produced in the separation layer 11 to some degree, and hence it is possible to reduce the force exerted on the separation layer 11 in the fourth process.

The method for exerting on the separation layer 11, the force acting in the direction to separate the first substrate 10 and the second substrate 14 is not specifically limited and various methods may be adopted. For example, as shown in FIG. 5, this can be performed by inserting a sharp edge body 30 into one edge between the first substrate 10 and the second substrate 14. The shape of the sharp edge body 30 is not specifically limited, however so that it is easily inserted between the substrates, preferably the shape is such that it has a narrow sharp edge, or such that the width becomes gradually wider from the narrow sharp part. For the first substrate 10 and the second substrate 14, it is preferable to previously form a notch or taper at the edge in order to form a gap between substrates, so that the sharp edge body can be easily inserted between the substrates by means of the gap. Further, after inserting the sharp edge body 30, vibration such as ultrasound may be applied to the sharp edge body 30 to facilitate exfoliation of the separation layer 11. Furthermore, the sharp edge body 30 may be twisted to rotate to thereby facilitate exfoliation of the separation layer 11.

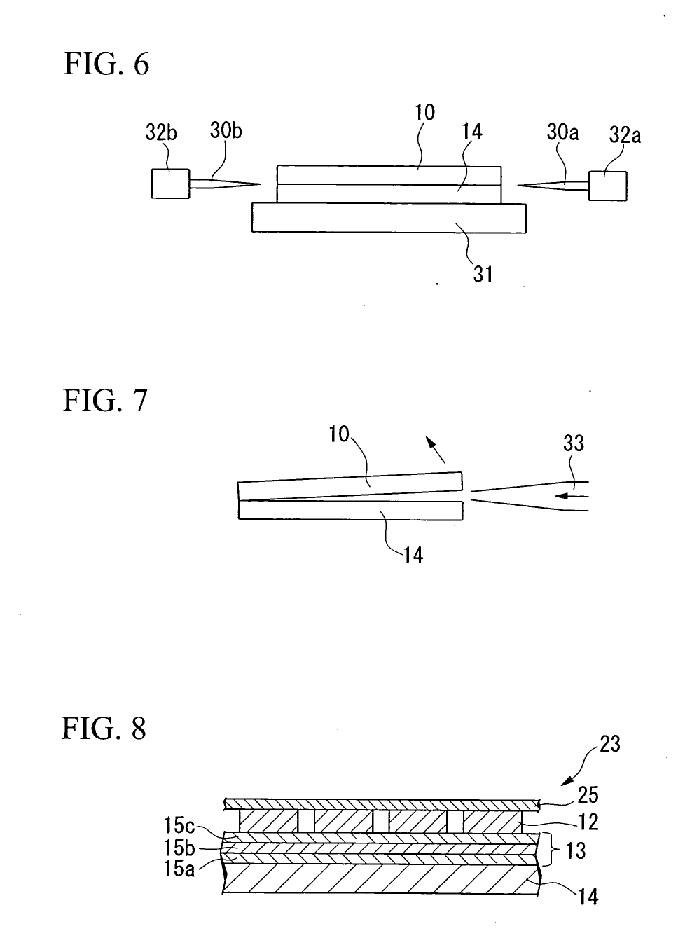

FIG. 6 is a schematic diagram showing an example of an exfoliation device furnished with the sharp edge body 30. Reference symbol 31 in FIG. 6 denotes a turntable for rotatably retaining the first substrate 10 and the second substrate 14. Around the turntable 31 are respectively arranged sharp edge bodies 30a and 30b. The sharp edge body 30a can be moved forward or back by a retaining device 32a for retaining the sharp edge body 30a. When moved forward by the retaining device 32a, it is inserted between the substrates on the turntable 31. The sharp edge body 30b can be moved forward or back by a retaining device 32b for retaining the sharp edge body 30b and can also be turned lengthwise about its axis. Therefore, the sharp edge body 30b is moved forward by the retaining device 32b, and is inserted between the substrates on the turntable 31, and is then twisted to turn to mutually separate the substrates.

In order to exfoliate between the substrates by the exfoliation device of such a construction, at first, the turntable 31 is turned so that edge of the substrate faces the tip of the sharp edge body 30a. Then, the sharp edge body 30a is moved forward by the retaining device 32a, to insert the tip of the sharp edge body 30a between the substrates by for example around 2 mm. Consequently, by inserting the tip of the sharp edge body 30a between substrates, the substrates are forced apart by the thickness of the tip, and hence the separation layer 11 is partially exfoliated. Next, the sharp edge body 30a is pulled back, and the turntable 31 is again turned so that the edge of the substrate on the side where the sharp edge body 30a was inserted, faces the sharp edge body 30b. The sharp edge body 30b is then moved forward by the retaining device 32a to insert the tip of the sharp edge body 30b between substrates. Then the sharp edge body 30b is twisted. Consequently, a force is applied in the direction to further separate the substrates, and as a result, the whole separation layer 11 is exfoliated. In this manner, after exfoliating the separation layer 11, the sharp edge body 30b is turned to return to the initial condition, and is then pulled back and removed from between the substrates.

By using two kinds of sharp edge bodies 30a and 30b in these different ways, it is possible to easily and reliably exfoliate the separation layer 11, and separate the first substrate 10 and the second substrate 14. For the sharp edge body 30, not only two kinds but three or more kinds may be prepared for separating the separation layer 11. In this case, for example, by gradually changing the width and the thickness of the tip of the sharp edge body 30, it is possible gradually change the force applied between the substrates rather than rapidly applying a strong force, to thereby enable smooth exfoliation of the separation layer 11. Further, in this case also, exfoliation of the separation layer 11 may be facilitated by twisting the sharp edge body 30.

An example of another method for exerting a force acting in the direction to separate the first substrate 10 and the second substrate 14, on the separation layer 11, as shown in FIG. 7, includes a method for injecting a high pressure gas 33 onto one edge between the first substrate 10 and the second substrate 14. The high pressure gas is not specifically limited and various kinds may be used. However, for example air since it is inexpensive is suitable, while nitrogen and argon being inert gases are also suitable. Furthermore as required, various kinds of reactant gas may be used which weaken the strength of the separation layer 11 by reacting with the separation layer 11, thus facilitating exfoliation.

As a method for injecting such gas, rather than injecting the gas at a constant flow rate, it may be intermittently injected by pulse control. Moreover the gas may be spirally injected by arranging guides on the injection side. Further, it is preferable to previously form a notch or taper at the edges of the first substrate 10 and the second substrate 14 in order to form a gap between the substrates, so that the high pressure gas can be easily injected between the substrates by injecting the gas into the gap. Furthermore, to avoid leakage of the gas except at the location where the high pressure gas is injected, it is preferable to seal between the substrates at places other than the injecting location. Moreover, the surroundings may be reduced in pressure to increase the differential pressure so that the high pressure gas can be easily injected between the substrates.

An example of another method for exerting a force acting in the direction to separate the first substrate 10 and the second substrate 14, on the separation layer 11, as shown in FIG. 11, includes a method for injecting a liquid onto one edge between the first substrate 10 and the second substrate 14. That is to say, this is a method for exfoliating the separation layer 11 by injecting liquid instead of the high pressure gas 33 as shown in FIG. 7. The liquid for injection is not specifically limited and various kinds may be used. However, for example water since it is inexpensive is suitable. Furthermore as required, various kinds of reactant liquid (exfoliative liquid) may be used which weaken the strength of the separation layer 11 by reacting with the separation layer 11, thus facilitating exfoliation.

In this case also, as a method for injecting such liquid, rather than injecting the liquid at a constant flow rate, it may be intermittently injected by pulse control. Moreover the liquid may be spirally injected by arranging guides on the injection side. Further, it is preferable to previously form a notch or taper at the edges of the first substrate 10 and the second substrate 14 in order to form a gap between the substrates, so that the liquid can be easily injected between the substrates by injecting the liquid into the gap.

An example of another method for exerting a force acting in the direction to separate the first substrate 10 and the second substrate 14, on the separation layer 11, includes a method for moving one of the edges of the first substrate 10 and the second substrate 14 in a direction to separate from the other edge of the first substrate and the second substrate. In this case, by previously changing the size of the first substrate 10 and the second substrate 14, or by adhering both substrates in a displaced position, the edge of one substrate can be displaced from that of the other substrate. Then, by applying a force to either of these edges in a direction to separate from the other substrate, and thus moving the substrate on the displaced side, the separation layer 11 is exfoliated.

An example of another method for exerting a force acting in the direction to separate the first substrate 10 and the second substrate 14, on the separation layer 11, includes the following method. That is to say, a thermal expansion material is provided on one edge of the separation layer 11 when forming the separation layer 11 in the abovementioned first process, and heat treatment is performed in the present fourth process in order to thermally expand the thermal expansion material. Examples of thermal expansion materials suitable for use include, metal powders with a large coefficient of thermal expansion. In the case of using the thermal expansion material, then for the constituent of the separation layer 11, it is preferable to use a material whose coefficient of thermal expansion is small, for example, an organic polymer material, a ceramic, or the like. The thermal expansion material is arranged on the one edge of the constituent materials, and in this condition, the separation layer 11 is formed, and further the elements 12 are formed thereon.

After forming the separation layer 11 in this manner, by performing the heat treatment in the fourth process, the thermal expansion material thermally expands and exerts a force acting in the direction to separate the first substrate 10 and the second substrate 14. Hence, it mainly produces interfacial exfoliation of the separation layer 11 so that the first substrate is reliably separated from the second substrate.

An example of another method for exerting a force acting in the direction to separate the first substrate 10 and the second substrate 14, on the separation layer 11, includes a method for laser ablating the separation layer 11 by irradiating laser light on one edge between the first substrate 10 and the second substrate 14. Examples of the laser light used include those which are used in the abovementioned pre-exfoliation process, that is to say, excimer lasers, Nd-YAG lasers, Ar lasers, CO₂ lasers, CO lasers and He—Ne lasers. Moreover, an optical fiber may be inserted between the substrates, and laser light irradiated onto the separation layer 11 through the optical fiber in order to perform laser ablation.

In this manner, exfoliation in the separation layer 11 is easily produced, and the first substrate 10 is reliably separated from the second substrate 14. Examples of methods in the fourth process for exerting a force acting in the direction to separate the first substrate 10 and the second substrate 14, include any one of the various methods enumerated above. However, these methods may also be sequentially performed in multiple combinations.

[Fifth Process]

After performing exfoliation in this manner, in a fifth process the first substrate 10 is removed (separated) from the second substrate 14 with the elements 12 adhered to the second substrate 14.

[Sixth Process]

Next, after removing the first substrate 10 in this manner, as shown in FIG. 8, a heat fusion sheet 25 containing heat sealing adhesive is arranged on the element 12, to form a thin film element providing substrate 23.

Examples of the heat fusion sheet 25, may use one kind or a combination of two or more kinds of thermal melting resins such as polyolefin resin (polyethylene, polypropylene, EVA, and the like), epoxy resin, fluorine resin, and acrylic resin containing a carboxyl group. The thickness of the heat fusion sheet 25 is around 0.1-100 μm, and preferably around 1-50 μm. The method of arranging the heat fusion sheet 25 on the element 12 is not specifically limited. For example, it may be easily arranged by a method involving placing a heat fusion sheet cut together with the second substrate 14, on the element 12 and pressing while heating. Further, rather than adhering the heat fusion sheet 25 onto the element 12 at this time, the sheet may be introduced at the time when the final a substrate 24 described later is mounted on the element 12.

There may be cases where the exfoliation residue of the separation layer 11 is adhered on the element 12 transferred to the second substrate 14, and it is desirable to completely remove this. A method for removing the residual separation layer 11 may involve suitably selecting and using such methods as, for example, washing, etching, ashing, grinding, or a combination of these.

Furthermore, in the case where the exfoliation residue of the separation layer 11 is adhered on the surface of first substrate 10 which has completed transfer of the elements 12, this may be removed in the same manner as for that on the element 12. As a result, it is possible to offer the first substrate 10 for recycling. By recycling the first substrate 10 in this way, manufacturing cost wastage can be eliminated. This is especially effective in the case where a first substrate 10 is made from a scarce material, or an expensive material such as silica glass is used.

[Seventh Process]

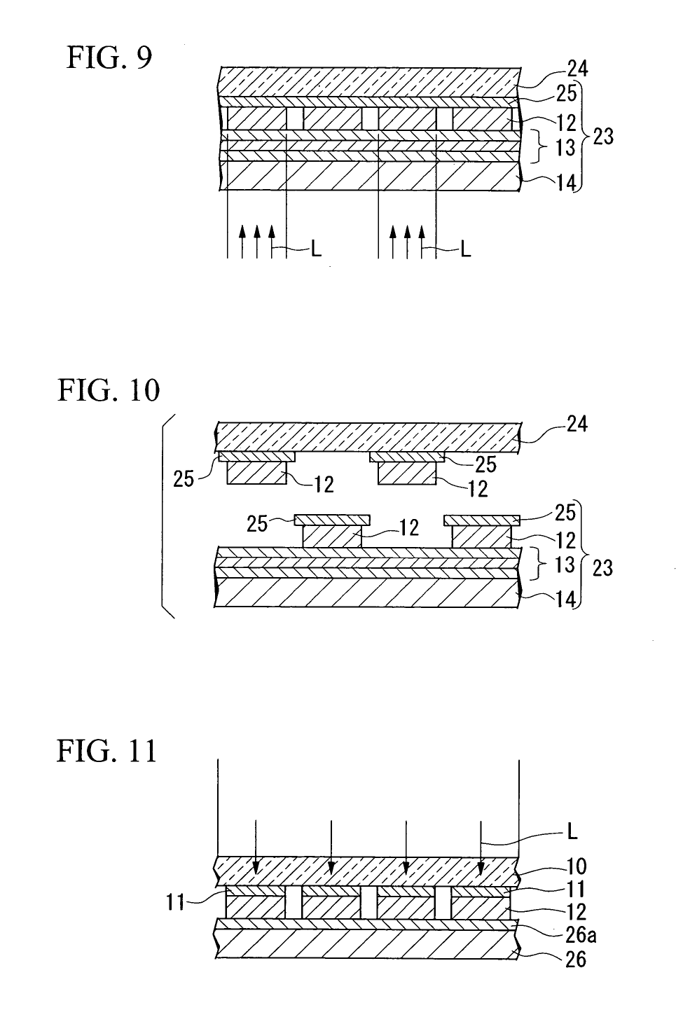

Next, as shown in FIG. 9, on the heat fusion sheet 25 of the thin film element providing substrate 23, is mounted the final substrate 24 onto which the elements 12 are to be transferred. Then light L is selectively irradiated only onto the area of the elements 12 to be transferred, so that only the elements 12 to be transferred are adhered onto the final substrate 24 for device forming.

The light L used here may be any type as long it can be received by the photoabsorption layer 15b of the multilayer film 13 to generate heat, and from the heat, it can cause adhesion by the heat fusion sheet 25. Examples include X-rays, ultraviolet rays, visible rays, infrared rays (heat rays), laser beams, milli-waves, micro-waves, electron rays, and radiations (.α.-rays, β-beta rays, and γ-rays). Among these, laser beams are preferable because they can easily generate heat in the photoabsorption layer 1 b, and are capable of highly accurate local irradiation. The laser used may be the same kind of laser light as used in the fourth process, or a different kind of laser light may be used.

By using such a thin film element providing substrate 23, the final substrate 24 to which transfer of the elements 12 is desired, is superposed on the thin film element providing substrate 23 so that it contacts with the heat fusion sheet 25, and the light L is selectively irradiated only onto the area of the elements 12 to be transferred. As a result, the heat generated in the adhesive layer 15c on which the light is irradiated, is conducted to the heat fusion sheet 25, and only the elements 12 to be transferred are adhered to the final substrate 24 via the heat sealing adhesive layer (the heat fusion sheet 25 which has once melted and solidified).

Therefore, by superposing the thin film element providing substrate 23 and the final substrate 24, and selectively irradiating light only on the part to be transferred, a part of or all of the many elements 12 on the thin film element providing substrate 23 side can be transferred accurately onto predetermined positions on the final substrate 24.

As the final substrate 24, it is preferable to have a degree of rigidity (strength), however, it may have flexibility or elasticity. Examples of such constituents include various synthetic resins or various glasses, specifically, various synthetic resins or normal (low melting point) inexpensive glasses are preferable.

Examples of synthetic resins include both thermoplastic resins and thermosetting resins, such as; polyolefins, e.g. polyethylene, polypropylene, ethylene-propylene copolymers, and ethylene-vinyl acetate copolymers (EVAs); cyclic polyolefins; modified polyolefins; polyesters such as polyvinyl chloride, polyvinylidene chloride, polystyrene, polyamides, poly-imides, polyamide-imides, polycarbonates, poly-(4-methylpentene-1), ionomers, acrylic resins, polymethyl methacrylate, acrylic-styrene copolymer (AS resin), butadiene-styrene copolymers, polio copolymers (EVOHs), polyethylene terephthalate (PET), polybutylene terephthalate (PBT), polycyclohexane terephthalate (PCT) and the like; polyethers, polyether-ketones (PEKs), polyether-ether-ketones (PEEKs), polyethe-imides, polyacetals (POMs); polyphenylene oxides; modified polyphenylene oxides; polyalylates; aromatic polyesters (liquid crystal polymers), polytetrafluoroethylene, polyvinylidene fluoride, and other fluorine resins; various thermoplastic elastomers such as styrene-, polyolefin-, polyvinyl chloride-, polyurethane-, fluorine rubber-, chlorinated polyethylene-type, and the like; epoxy resins, phenol resins, urea resins, melamine resins, unsaturated polyesters, silicone resins, polyurethanes, and the like; and copolymers, blends, polymer alloys essentially consisting of these synthetic resins. One or more of these synthetic resins may be used in combination (for example, as a composite consisting of at least two layers).

Examples of glass include, silicate glass (quartz glass), alkaline silicate glass, soda-lime glass, potash lime glass, lead (alkaline) glass, barium glass, and borosilicate glass. All the types of glass other than silicate glass have lower melting points than that of silicate glass. Moreover, they are comparatively easy to form and process, and inexpensive, and therefore preferable.

In the case of using a substrate manufactured from synthetic resin as the final substrate 24, various advantages can be obtained such as; large size final substrates can be integrally manufactured; even complex forms having curved surfaces, or concave-convex surfaces, or the like can be easily manufactured; and material cost and manufacturing cost are inexpensive. Hence, usage of synthetic resin is advantageous when manufacturing large size and inexpensive devices (for example, liquid crystal displays).

The final substrate 24, may constitute its own independent device, for example, such as with a liquid crystal cell, or it may constitute a part of a device, for example, such as with a color filter, an electrode layer, a dielectric layer, an insulation layer, and a semiconductor element.

[Eighth Process]

Next, as shown in FIG. 10, by applying a force on the thin film element providing substrate 23 and the final substrate 24, in the direction to separate the both, the thin film element providing substrate 23 is removed from the final substrate 24. By drawing the thin film element providing substrate 23 away from the final substrate 24, then as shown in FIG. 10, the elements 12 are transferred to multiple positions on final substrate 24. On the other hand, elements which are not transferred remain on thin film element providing substrate 23.

The thin film element providing substrate 23 on which untransferred elements 12 remain, can be used for successively transferring many elements 12 onto other final substrates 24 by repeating the seventh and eighth processes. That is to say, in the case where the manufacturing method for a device of the present invention is applied, for example, to a manufacturing method for an active matrix substrate for an electro-optic device, microscopic elements 12 such as TFTs can be dispersingly arranged effectively for each of the many pixels on substrate.

Through the above respective processes, many elements 12 to be transferred can be selectively transferred onto the final substrate 24. Then, the transferred elements 12 are connected to the wiring on the final substrate 24 by wiring formed by various methods, a desired protective film is formed, and the finally obtained devices are combined with other components, to form into a device.

In the present embodiments, the configuration in such that; a heat fusion sheet is used for the external layer of the thin film element providing substrate 23; sealing heat is produced by the heat generated by light irradiation; and the elements 12 are transferred onto the final substrate 24. However, photoresist may be used instead of the heat fusion sheet in order to transfer the elements 12 to be transferred onto the final substrate 24 by local irradiation of light. In this case, the photoabsorption layer 15b and the protective layer 15a need not be provided.

According to such a device manufacturing method, the many elements 12 which are to be dispersingly arranged at intervals on the final substrate 24 can be concentratedly manufactured on the first substrate 10. Hence, compared to the case where the elements 12 are directly formed on the final substrate 24, the area efficiency in the manufacture of the elements 12 can be greatly increased, and a final substrate 24 with the many elements 12 dispersingly arranged can be effectively manufacture at low cost.

Moreover, it becomes easily feasible to select and remove before transfer, any of the many elements 12 which are concentratedly manufactured on the first substrate 10. As a result product yield rate can be increased.

Furthermore, since a force acting in the direction to separate the first substrate 10 and the second substrate 14, is exerted on the separation layer 11 between the first substrate 10 and the second substrate 14 from the one edge of these substrates, exfoliation of the separation layer 11 in the layer and/or on the interface is easily produced. As a result, the separation layer 1 and the elements 12 are separated, and the elements 12 can be reliably transferred onto the second substrate 14.

Furthermore, the same or different elements 12 can be laminated and united. Therefore, by uniting elements manufactured under different process conditions, elements having a laminated structure which are conventionally difficult to manufacture can be provided, and elements having a three-dimensional structure can be easily manufactured.

Further, since the easily handled thin film element providing substrate 23 which transfers of all of the elements 12 formed on the first substrate 10 onto the second substrate 14 is made, and then the thin film element providing substrate 23 is superimposed onto the final substrate 24, to transfer only the elements 12 to be transferred to the final substrate 24, the elements 12 can be transferred onto the final substrate 24 while keeping the vertical relationship of the laminated structure of the elements 12 formed on the first substrate 10. Therefore, extra improvement such as changing the position of external joining terminals in order to handle cases where the vertical relationship is reversed, is not necessary, so that it is possible to manufacture elements using an existing element manufacturing process.

In the device obtained by such manufacturing methods, since the elements constituting this are accurately positioned on the final substrate 24, then different from the macrostructure used in the conventional microstructure arrangement techniques, the extra symmetrical circuit structure becomes unnecessary. Hence, extremely small microscopic blocks on which are formed only the circuits to meet minimum requirements are possible. Therefore, a very large number of elements 12 can be concentratedly manufactured on the first substrate 10 and the cost per element is greatly reduced, so that the device itself is also reduced in cost.

In the above examples, the final substrate is prepared separately to the second substrate 14, and the elements 12 on the second substrate 14 are transferred to this. However, the present invention is not limited to this and the second substrate 14 may be the final substrate for device forming.

Furthermore, rather than performing the pre-exfoliation process as described above, the fourth process may be performed directly after finishing the third process, to thereby exfoliate the separation layer 11 to remove the first substrate 10 from the second substrate 14.

### [Second Embodiment]

FIG. 11 to FIG. 14 are explanatory diagrams of a second embodiment of a manufacturing method for a device of the present invention. This manufacturing method is provided with the following processes (a) to (j).

[(a) Process]

(a) Process forms the separation layer 11 on the first substrate 10. The preferable materials for the first substrate 10, preferable materials for the separation layer 11, and the method of forming the separation layer 11 can be performed in the same way as for the [first process] of the first embodiment described above.

[(b) Process]

Next, many elements 12 are formed on the separation layer 11. This (b) process can be performed in the same way as for the [second process] of the first embodiment described above.

[(c) Process]

Next, the elements of the first substrate 10 and the second substrate 26 (refer to FIG. 11) are adhered via a temporary adhesive layer 26a comprising a solvent soluble adhesive.

The solvent soluble adhesive constituting the temporary adhesive layer 26a can be appropriately selected for use from adhesives which are comparably easily dissolved by solvents such as water, alcohol, acetone, ethyl acetate, toluene, or the like, so that the adhered body can be peeled away. Examples include, many organic solvent soluble ashesives such as polyvinyl alcohol-type, aqueous vinyl urethane-type, acrylic-type, polyvinyl pyrrolidone, alpha-olefin, maleate-type, and photocurable adhesives.

This temporary adhesive layer 26a can be applied to the whole surface of the second substrate, or can be applied only onto the elements 12. The thickness of the temporary adhesive layer 26a is optional as long as it can reliably adhere the elements 12, and is suitably selected corresponding to the adhesive strength of adhesive to be used. The method of forming the temporary adhesive layer 26a may be performed by using a method such as spin coating, inkjet coating, printing, or the like.

The material and the thickness used for the second substrate 26 are not specifically limited, and for example a substrate of an equivalent material and thickness to that of the second substrate 14 used in the first embodiment may be used.

[(d) Process]

Next, as shown in FIG. 11, light, preferably laser light is irradiated from the first substrate 10 side onto the temporary adhered body in a laminated condition of the second substrate 26, the temporary adhesive layer 26a, the elements 12, the separation layer 11, and the first substrate 10, so as to produce partial exfoliation in the layer and/or on the interface of the separation layer 11.

The irradiating light for exfoliation of the separation layer 11 is light similar to the light used in the pre-exfoliation process of the first embodiment, in particular the laser light, and is irradiated under similar conditions.

[(e) Process]

Next, a force acting in the direction to separate the first substrate 10 and the second substrate 26 is applied from the one edge of those substrates, to the separation layer 11 between the first substrate 10 and the second substrate 26, so that it produces exfoliation in the layer and/or on the interface of the separation layer 11. As a method for applying the force acting in the direction to separate the first substrate 10 and the second substrate 26, to the separation layer 11, the various methods given in the fourth process in the first embodiment can be adopted.

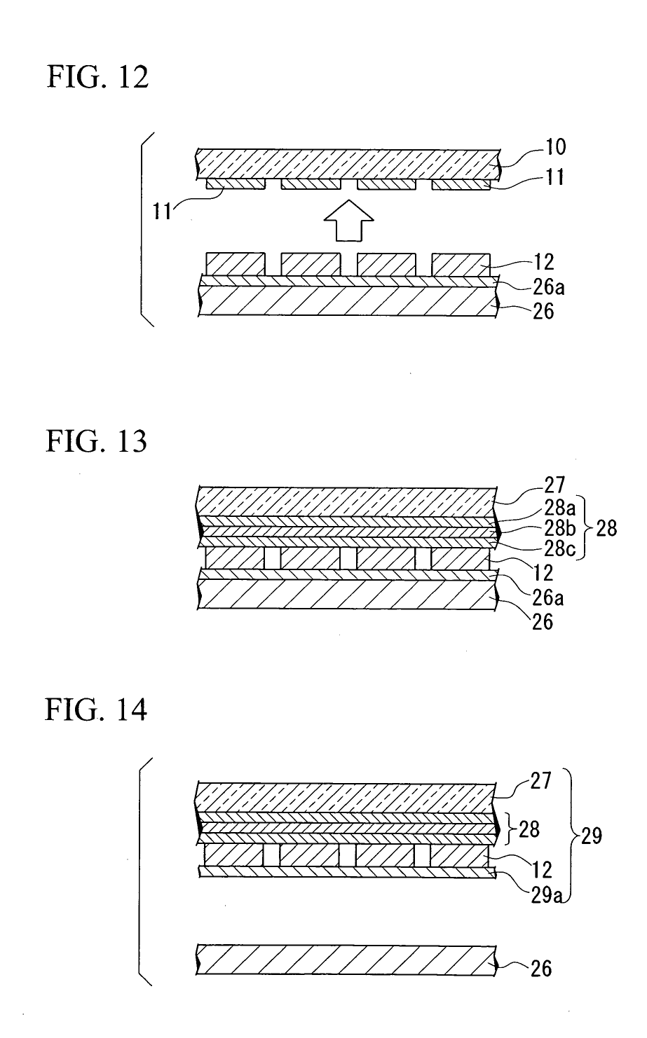

After the exfoliation, as shown in FIG. 12, the first substrate 10 is removed from the elements 12. There may be cases where the exfoliation residue of the separation layer 11 is adhered on the element 12 transferred to the second substrate 26, and it is desirable to completely remove this. A method for removing the residual separation layer 11 may involve suitably selecting and using such methods as, for example, washing, etching, ashing, grinding, or a combination of these. Furthermore, the exfoliation residue of the separation layer 11 adhered on the surface of first substrate 10 which has completed transfer of the elements 12 may be removed by the same method. As a result, it is possible to offer the first substrate 10 for recycling. By recycling the first substrate 10 in this way, manufacturing cost wastage can be eliminated. This is especially effective in the case where a first substrate 10 is made from a scarce material, or an expensive material such as silica glass is used.

[(f) Process]

Next, as shown in FIG. 13, the second substrate 26 to which all of the elements 12 have been transferred, and a third substrate 27 formed with a multilayer film 28 comprising a protective layer 28a, a photoabsorption layer 28b, and an adhesive layer 28c which have been previously sequentially laminated on the substrate, are superimposed, so that all of the elements 12 are adhered via the adhesive layer 28c to the third substrate 27.

For the configuration of the multilayer film 28, a configuration similar to that of the multilayer film 13 used in the first embodiment, is used. Here, the material and the thickness used for the third substrate 27 are not specifically limited, and for example, a substrate of an equivalent material and thickness to that of the second substrate 14 used in the first embodiment may be used.

[(g) Process]

Next, by using solvent to dissolve the temporary adhesive layer 26a, the temporary adhesive layer 26a is melted away and the second substrate 26 is removed from the elements 12.

Dissolving the temporary adhesive layer 26a can be performed by methods such as soaking a part of (second substrate side) or all of the temporary adhered body shown in FIG. 13 in a suitable solvent such as water or organic solvent, or by spraying the solvent. After removing the second substrate 26, it is desirable to completely remove the residual solvent by hot air drying or the like.

[(h) Process]

Next, after removing the second substrate 26, as shown in FIG. 14, a heat fusion sheet 29a containing a heat sealing adhesive is attached to the elements 12, and a thin film element providing substrate 29 of a structure where the multilayer film 28, the elements 12, and the heat fusion sheet 29a are sequentially laminated on the third substrate 27, is formed.

The heat fusion sheet 29a, may use one similar to the heat fusion sheet 25 used in the first embodiment. Moreover, the method of arranging the heat fusion sheet 29a, may be performed in a similar way to that for the heat fusion sheet 25 used in the first embodiment.

The thin film element providing substrate 29, by performing an (i) process and a (j) process described later, may be used similarly to the thin film element providing substrate 23 used in the first embodiment, to selectively transfer the elements 12 onto the final substrate. However, compared to the thin film element providing substrate 23 used in the first embodiment, the vertical relationship of the laminated structure of the elements 12 to be transferred onto the final substrate is reversed.

[(i) Process]Next, by superposing the final substrate (not shown) onto the heat fusion sheet 29a side of the thin film element providing substrate 29, and irradiating light similarly to for the [seventh process] of the first embodiment, only the elements 12 to be transferred are transferred onto the final substrate (refer to FIG. 9).

For the final substrate to be used and the light irradiating condition, this may be performed similarly to for the [seventh process] of the first embodiment.

[(j) Process]

Next, by drawing the thin film element providing substrate 29 away from the final substrate, the final substrate where the elements 12 are transferred in the desired position (refer to FIG. 10) is obtained.

Also in this device manufacturing method, the area efficiency in the manufacture of the elements 12 can be greatly increased, and a final substrate with the many elements 12 dispersingly arranged can be effectively manufactured at low cost.

Moreover, it becomes easily feasible to select and remove before transfer, any of the many elements 12 which are concentratedly manufactured on the first substrate 10. As a result product yield rate can be increased.

Furthermore, since a force acting in the direction to separate the first substrate 10 and the second substrate 26, is exerted on the separation layer 11 between the first substrate 10 and the second substrate 26 from the one edge of these substrates, exfoliation of the separation layer 11 in the layer and/or on the interface is easily produced. As a result, the separation layer 11 and the elements 12 are separated, and the elements 12 can be reliably transferred onto the second substrate 26.

Furthermore, an element having a laminated structure which is conventionally difficult to manufacture can be provided, and an element having a three-dimensional structure can be easily manufactured.

Here, devices obtained by such a manufacturing method, are not specifically limited, and the method is applicable to any device as long as a constituent is an element such as a semiconductor element or an optical element. The method can be applied to various devices, for example, various kinds of semiconductor devices having switching elements such as memories or TFTs, electro-optic devices such as organic electroluminescence devices, liquid crystal displays, electrophoresis apparatus, plasma display units, and also optical devices such as laser equipment.

In particular, in the case where an electro-optic device such as an organic electroluminescence device, a liquid crystal display, an electrophoresis apparatus, or a plasma display unit are manufactured by applying the manufacturing method for a device of the present invention, it is possible to manufacture at low cost, and product yield rate can be increased, enabling a cost reduction. Consequently, for the obtained electro-optic device, productivity is high and cost is low.

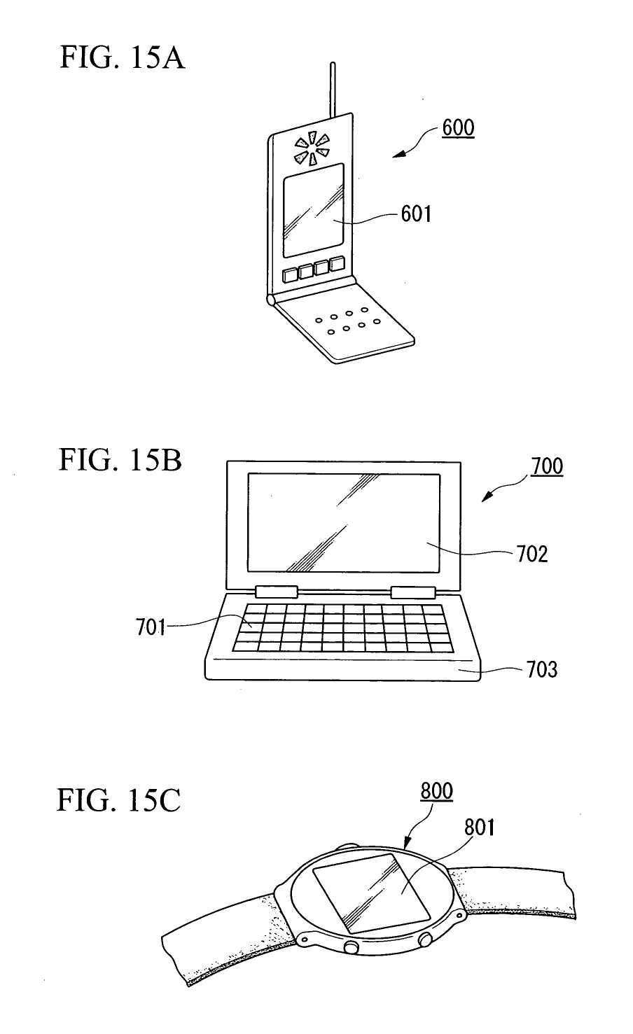

Examples of electronic equipment of the present invention are those having the abovementioned electro-optic device as a display panel, specifically as shown in FIG. 15.

FIG. 15(a) is a perspective view showing an example of a mobile phone. In FIG. 15(a), reference numeral 600 denotes the main body of the mobile phone, and 601 denotes a display panel having the abovementioned electro-optic device.

FIG. 15(b) is a perspective view showing an example of a portable information processor such as word processor or personal computer. In FIG. 15(b), reference numeral 700 denotes an information processor, 701 denotes an input section such as keyboard, 703 denotes a main body of the information processor, and 702 denotes a display panel having the abovementioned conductive pattern 4 (conducting film pattern).

FIG. 15(c) is a perspective view showing an example of a watch type electronic equipment. In FIG. 15(c), reference numeral 800 denotes a main body of the watch and 801 denotes a display panel having the abovementioned electro-optic device.

The electronic equipment shown in FIG. 15(a) to (c) are furnished with display panels having the abovementioned electro-optic devices, thus giving a high productivity low cost product.

As described above, according to the manufacturing method for a device of the present invention, many elements which are to be dispersingly arranged in intervals on the final substrate are concentratedly manufactured on the first substrate. Therefore devices can be manufactured effectively at low cost.

Moreover, the many elements which are concentratedly manufactured on the first substrate can be easily selected and removed before the transfer. As a result, product yield rate can be increased.

Furthermore, since a force acting in a direction to separate the first substrate and the second substrate is exerted on the separation layer from the edge of these substrates, exfoliation can be easily produced in the separation layer. As a result, the separation layer and the elements can be separated, and the elements can be reliably transferred onto the second substrate.

Furthermore, an element having a laminated structure which is conventionally difficult to manufacture can be provided, and an element having a three-dimensional structure can be easily manufactured.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description and is only limited by the scope of the appended claims.

1. A manufacturing method for a device in which some or all of plural elements formed on a first substrate, are transferred to a second substrate, and some or all of the transferred elements are used to manufacture the device, the method comprising: a first process for forming an separation layer on said first substrate; a second process for forming many elements on said separation layer; a third process for adhering the elements to be transferred on said first substrate, to said second substrate via an adhesive layer; a fourth process for exerting a force acting in a direction to separate said first substrate and said second substrate on the separation layer between said first substrate and said second substrate from one edge of those substrates, to execute exfoliation in the layer and/or on an interface of the separation layer; and a fifth process for separating said first substrate from which the transfer of elements has been completed, from said second substrate.

2. A manufacturing method for a device according to claim 1, wherein the transfer of the elements from said first substrate to said second substrate comprising a step of collectively transferring all the elements formed on said first substrate.

3. A manufacturing method for a device according to claim 1, further comprising: a sixth process for forming after separating said first substrate from said second substrate, a thin film element providing substrate by providing a heat fusion sheet containing heat sealing adhesive on said elements which have been transferred to said second substrate; a seventh process for superposing a final substrate so that it contacts with said heat fusion sheet of said thin film element providing substrate, selectively irradiating light only on the area of said elements to be transferred, and adhering only said elements to be transferred onto the final substrate for device forming; and an eighth process for removing said thin film element providing substrate having untransferred elements, from the final substrate to which said elements have been transferred.

4. A manufacturing method for a device according to claim 1, having a pre-exfoliation process between said third process and said fourth process, for selectively irradiating light onto said separation layer between said elements to be transferred and said first substrate, to execute exfoliation in the layer and/or on the interface of said separation layer.

5. A manufacturing method for a device according to claim 1, wherein said fourth process is performed by inserting a sharp edge body into one edge between said first substrate and said second substrate.

6. A manufacturing method for a device according to claim 1, wherein said fourth process is performed by injecting a high pressure gas into one edge between said first substrate and said second substrate.

7. A manufacturing method for a device according to claim 1, wherein said fourth process is performed by injecting a liquid into one edge between said first substrate and said second substrate.

8. A manufacturing method for a device according to claim 1, wherein said fourth process is performed by moving one of the edges of said first substrate and said second substrate in a direction to separate from the other of the edges of said first substrate and said second substrate.

9. A manufacturing method for a device according to claim 1, wherein said a thermal expansion material is provided in one edge of said separation layer when forming said separation layer in said first process, and said fourth process is performed by thermal expansion of said thermal expansion material by heat treatment.

10. A manufacturing method for a device according to claim 1, wherein said fourth process is performed by laser ablating said separation layer by irradiating laser light onto one edge between said first substrate and said second substrate.

11. A device obtained by a manufacturing method according to claim 1.

12. An electro-optic device provided with devices according to claim 11.

13. An electronic equipment provided with the devices according to claim 11.
